(19) United States
(12) Patent Application Publication
(10) Pub. No.: US 2008/0280389 A1
(43) Pub. Date: Nov. 13, 2008

(54) CAMERA MODULE AND METHOD FOR ASSEMBLING SAME

(75) Inventors: JEN-CHAO WANG, Tu-Cheng (TW); AN-CHANG LEI, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/923,045

(22) Filed: Oct. 24, 2007

(30) Foreign Application Priority Data
May 11, 2007 (CN) 200710200600.2

(51) Int. Cl. H01L 21/02; H01L 31/00

(52) U.S. Cl. 438/73; 257/E31.001; 257/E21.003

(57) ABSTRACT

A method for assembling a camera module includes following steps: providing a circuit board having a connecting region; disposing a liquid anisotropic conductive adhesive on the connecting region of the circuit board; placing an image sensor module, on the connecting region of the circuit board; thermal press-bonding the image sensor module onto the circuit board to fix the image sensor module with the circuit board. Because the anisotropic conductive adhesive before being disposed on the circuit board is liquid and doesn't needs to be cut, flow-shop operations are easy to achieve, and costs are decreased.

### RELATED FIELD

The present invention relates to an assembling technology of camera modules, and more particularly, to a camera module and a method for assembling the same.

### BACKGROUND

A camera module includes at least a circuit board and an image sensor device electrically connected with the circuit board. A typical assembling method is to connect the image sensor device and fix it to a surface of the circuit board by use of an anisotropic conductive film (ACF).

In the typical assembling method, the ACF is in a semisolid state and composed of an adhesive resin of a thermosetting type with conductive particles mixed therein. The ACF is formed in a film-like shape on a base film while being protected by a cover film. Due to the ACF being in a semisolid state, when it is affixed on the circuit board in assembling process, it must be cut so as to match with the size of the circuit board. So, although the assembling method may be suitable for mono-station operation, it is not suitable for flow-shop operation. Thus, assembly costs are increased, and error rates of the assembled camera module can be increased because of manual errors.

### SUMMARY

In accordance with an embodiment, an exemplary method for assembling a camera module includes the following steps.

providing a circuit board having a connecting region;
disposing a liquid anisotropic conductive adhesive on the connecting region of the circuit board;
placing an image sensor module on the connecting region of the circuit board;
thermal press-bonding the circuit board with the image sensor module disposed thereon to fix the image sensor module with the circuit board. A camera module is also presented.

### BRIEF DESCRIPTION OF THE DRAWINGS

The present invention is described in detail hereinafter, by way of example only, through description of a preferred embodiment thereof and with reference to the accompanying drawing in which:

FIG. 1 is a flow chart of a method of assembling an image sensor module onto a circuit board in accordance with an embodiment of the present invention.

FIG. 2 is a schematic view of the circuit board of FIG. 1;

FIG. 3 is a schematic isometric view showing an anisotropic conductive adhesive for use in the assembling method of FIG. 1 in accordance with the embodiment;

FIG. 4 is a schematic cross-sectional view of the image sensor module of FIG. 1;

FIG. 5 is a schematic cross-sectional view of an assembled camera module in accordance with the embodiment of the present invention; and

FIG. 6 is an enlarged schematic cross-sectional view of a part VI of the camera module of FIG. 5.

### DETAILED DESCRIPTION OF THE PREFERRED EMBODIMENTS

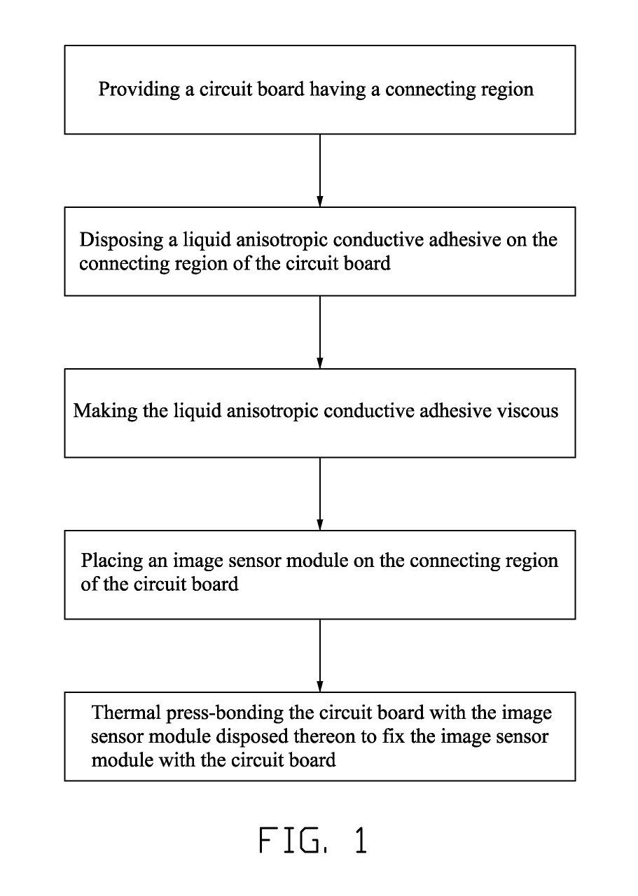

The detailed explanation of an assembling method for a camera module according to the present invention will now be made with reference to the drawing attached hereto. Referring to FIG. 1, the method for assembling the camera module includes following steps:

In step 1, a circuit board having a connecting region is provided.

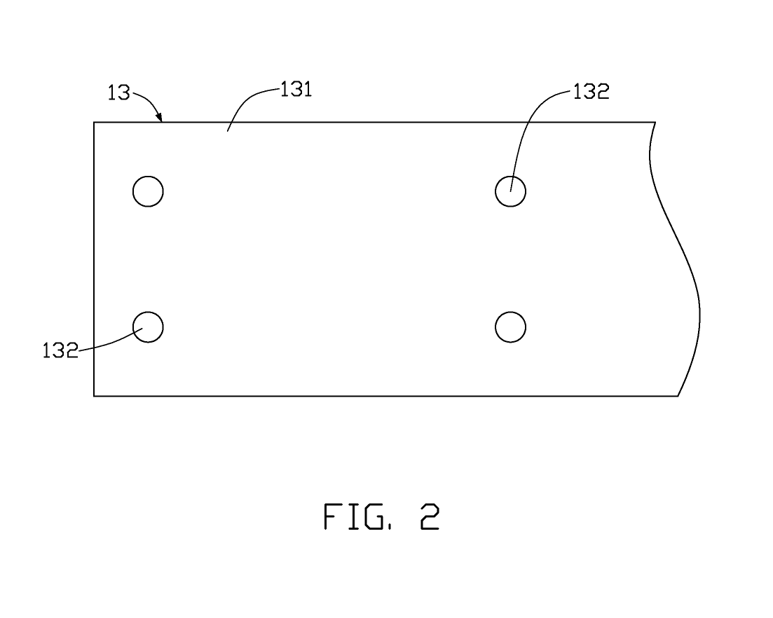

Referring to FIG. 2, a circuit board 13 has a connecting region 131. A number of pads 132 are formed on the connecting region 131 protruding from the surface of the connecting region 131. The pads 132 are electrically connected a conductor (not shown) of the circuit board 13 and configured for transmitting signals. It can be appreciated that the circuit board 13 is a flexible board made from ceramic, thermosetting resin or the like. In the present embodiment, the circuit board 13 is made from a thermosetting resin.

In Step 2, a liquid anisotropic conductive adhesive is disposed on the connecting region of the circuit board.

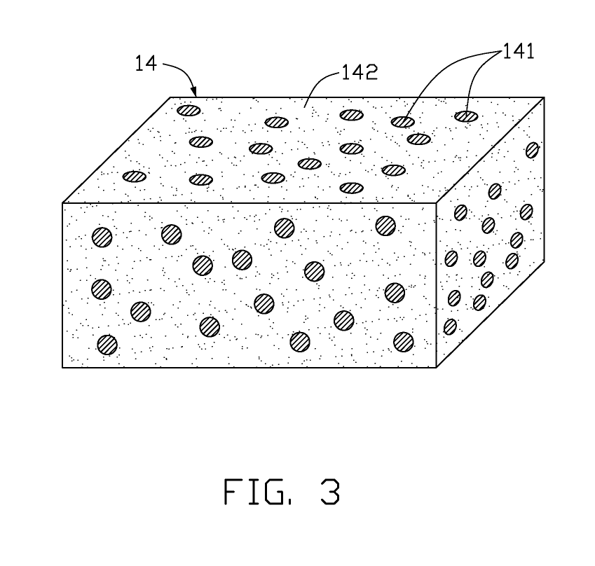

Referring to FIG. 3, a schematic isometric view of an anisotropic conductive adhesive (ACA) 14 is shown. An initial state of the ACA 14 is liquid. The ACA 14 is composed of an adhesive resin 142 with a number of conductive particles 141 mixed therein. The conductive particles 141 have a grain size in a range of 3 to several tens of micrometers. The adhesive resin 142 is made from an insulating and thermosetting resin such as an epoxy resin, a phenolic resin, and so forth. The conductive particles 141 can be metallic particles or resin particles. The metallic particles are made from silver or solder. The resin particles are made from a plastic with gold (Au) plating applied on the surface thereof. In the present embodiment, the conductive particles 141 are metallic particles. The ACA 14 can be disposed on the circuit board 13 using a printer or a dispenser. When using the printer, the printing method can be screen printing, steel printing and so on. In the present embodiment, the ACA 14 is disposed on the circuit board 13 using a dispenser (not shown) for a predetermined time and air-pressure via a processor.

In step 3, the liquid anisotropic conductive adhesive is made viscous.

After the liquid ACA 14 is disposed on the connecting region 131 of the circuit board 13, it can be appreciated that the ACA 14 is made viscous in order to make the ACA 14 remain in a condition of low fluidity and high viscosity. A method of making the liquid ACA 14 viscous can be a baking process, or exposing the circuit board 13 having the liquid ACA 14 disposed thereon to air for a while. In the present embodiment, the method of making the liquid ACA 14 viscous is with a baking process using an oven by applying a first temperature. The first temperature is less than a curing temperature of the ACA 14. The oven can be a snap cure oven, and so forth. The time and the first temperature of baking are set according to characteristics of the adhesive resin 142.

In step 4, the image sensor module to be assembled is placed on the connecting region of the circuit board.

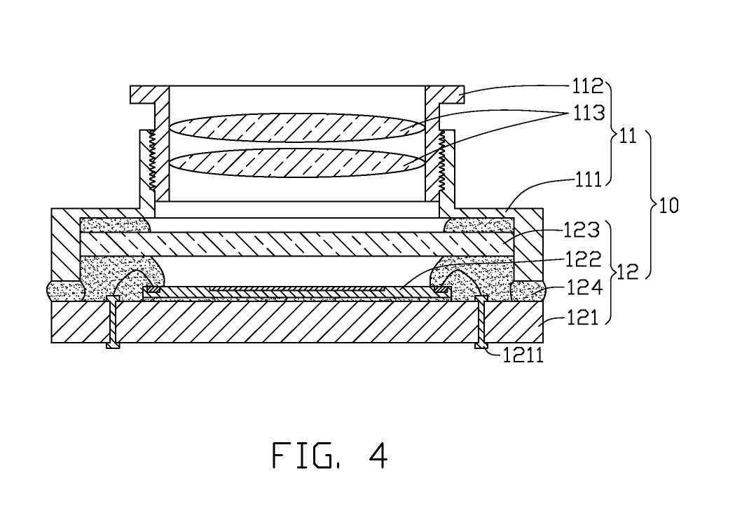

Referring to FIG. 4, an image sensor module 10 includes a lens module 11 and an image sensor 12. The lens module 11 is configured for imaging. The image sensor 12 configured for capturing images is disposed in an image side of the lens module 11 and connected with the lens module 11.

The lens module 11 includes a holder 111, a barrel 112 disposed in an end of the holder 111 and a lens assembly 113 received in the barrel 112.

The image sensor 12 includes a base 121, an image sensor chip 122 disposed on the base 121 and electronically connected to the base 121, a transparent cover 123 positioned above the image sensor chip 122, and an adhesive 124 configured for gluing the transparent cover 123 to the base 121. The image sensor chip 122 is received in a sealing chamber formed by the base 121, the transparent cover 123 and the adhesive means 124, and configured for capturing images and transforming image signals into electronic signals. A number of bumps 1211 corresponding to the pads 132 are provided on an opposite side to the side of the base 121 where the image sensor chip 122 is disposed. The bumps 1211 are electrically connected with the image sensor chip 122 configured for transmitting the electronic signals transformed by the image sensor chip 122 to other elements, such as the circuit board 13.

The image sensor module 10 is placed on the connecting region 131 of the circuit board 13 using a suction nozzle, a jaw, or the like. In the embodiment, the jaw (not shown) is used. It can be appreciated that the jaw includes an aligning lens disposed on the jaw and an arm configured for controlling the jaw to act. The arm controls the jaw to align the bumps 1211 provided on the base 121 with the pads 132 formed on the circuit board 13 in cooperation with the aligning lens.

In step 5, the circuit board with the image sensor module disposed thereon is thermal press-bonded to fix the image sensor module to the circuit board.

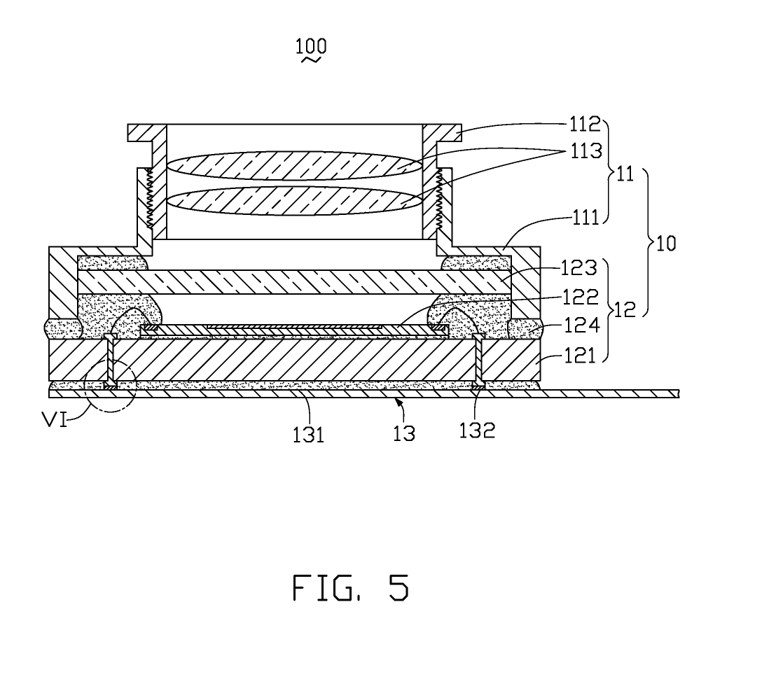

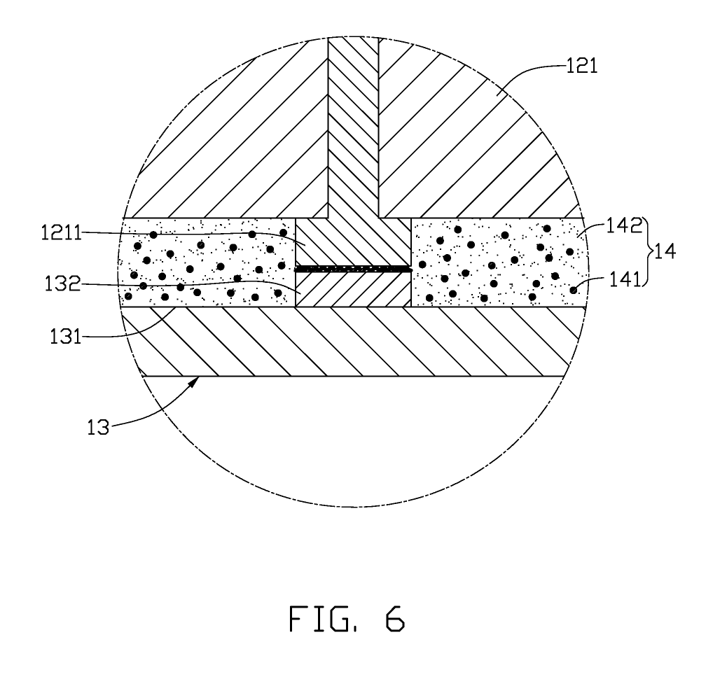

Referring to FIGS. 5 and 6, the image sensor module 10 is placed on the connecting region 131 of the circuit board 13 after aligning the respective pads 132 formed on the circuit board 13 with the respective bumps 1211 formed on the base 121 of the image sensor module 10. Subsequently, a heating and pressurizing process is applied by use of the heating and pressurizing tool (not shown) provided with a built-in heater so as to fix the image sensor module 10 to the circuit board 13. Because the pads 132 protrude out of the surface of the connecting region 131 of the circuit board 13 and the bumps 1211 protrude from the surface of the base 121, a pressure applied during the heating and pressurizing process extrudes the adhesive resin 142 contained in the ACA 14 located in a space between the bumps 1211 of the image sensor module 10 and the pads 132 of the circuit board 13 out of the space to cause the conductive particles 141 contained in the ACA 14 to contact with the bumps 1211 of the image sensor module 10, and the pads 132 of the circuit board 13, thereby effecting electric conduction therebetween. At this point in time, the adhesive resin 142 has been cured in the curing temperature, applied during the heating and pressurizing process, so that the conductive particles 141 can be held and sandwiched between the pads 132 and the bumps 1211.

After the heating and pressurizing process, the assembling of the camera module 100 including the image sensor module 10, the circuit board 13, and the ACA 14 is completed.

It can be understood, the electric conduction between the image sensor module 10 and the circuit board 13 is effective as long as one of the pads 132 of the circuit board 13 and the pumps 1211 of the image sensor module 10 protrude from the surface where the pads 132 or the pumps 1211 are disposed.

The image sensor module is assembled together with the circuit board using the liquid ACA in the assembling method. Because the ACA, before being disposed on the circuit board, is liquid and doesn't need to be cut, flow-shop operations are easy to achieve, and costs are decreased.

It can be understood that the above-described embodiment are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. A method for assembling a camera module, comprising:
providing a circuit board having a connecting region;
disposing a liquid anisotropic conductive adhesive on the connecting region of the circuit board;
placing an image sensor module on the connecting region of the circuit board;
thermal press-bonding the circuit board with the image sensor module disposed thereon to fix the image sensor module to the circuit board.

2. The method as claimed in claim 1, further comprising a step of making the anisotropic conductive adhesive viscous.

3. The method as claimed in claim 2, wherein the anisotropic conductive adhesive is made viscous by a baking process using an oven.

4. The method as claimed in claim 3, wherein the oven used in the baking process is a snap cure oven.

5. The method as claimed in claim 1, wherein the anisotropic conductive adhesive is disposed on the connecting region of the circuit board using a printing technology.

6. The method as claimed in claim 5, wherein the printing technology is screen printing.

7. The method as claimed in claim 5, wherein the printing technology is steel printing.

8. The method as claimed in claim 1, wherein the anisotropic conductive adhesive is disposed on the connecting region of the circuit board using a dispenser.

9. The method as claimed in claim 1, wherein the image sensor module has a base with a plurality of bumps disposed thereon, and the connecting region of the circuit board has a plurality of pads disposed thereon corresponding to the bumps.

10. A camera module comprising:
a circuit board having a connecting region;
an image sensor module, and
an anisotropic conductive adhesive cured from liquid to solid and sandwiched between the connecting region of the circuit board and the image sensor module, the image sensor module being electronically connected to the circuit board via the anisotropic conductive adhesive.

11. The camera module as claimed in claim 10, wherein the circuit board is a flexible board.

12. The camera module as claimed in claim 1, wherein the circuit board is made from one of ceramic and thermosetting resin.

13. The camera module as claimed in claim 10, wherein the image sensor module has a base with a plurality of bumps disposed thereon, and the connecting region of the circuit board has a plurality of pads disposed thereon corresponding to the bumps.

14. The camera module as claimed in claim 13, wherein one of the pads of the circuit board and the pumps of the image sensor module protrude from the surface where the pads or the pumps are disposed.

15. A camera module comprising:
a circuit board having a connecting region with a plurality of pads disposed thereon;
an image sensor module having a base with a plurality of bumps disposed thereon; and
an anisotropic conductive adhesive cured from liquid to solid and sandwiched between the connecting region of the circuit board and the image sensor module to secure the image sensor module to the circuit board, the anisotropic conductive adhesive comprising an adhesive resin and a plurality of conductive particles mixed in the adhesive resin, the conductive particles located between the pads and the bumps electrically connecting the pads with the bumps respectively to thereby electronically connect the image sensor module to the circuit board.
